(19) United States
(12) Patent Application Publication
(10) Pub. No.: US 2026/0118380 A1
(43) Pub. Date: Apr. 30, 2026

(54) PROBE SYSTEM, PROBE CARD, PROBE HEAD AND METHOD FOR TESTING ELECTRONIC DEVICE UNDER TEST INTEGRATED ON A SEMICONDUCTOR WAFER, AND ELECTRONIC DEVICE TESTED BY THE PROBE CARD

(71) Applicant: MPI CORPORATION, Zhubei City (TW)

(72) Inventors: CHIN-YI LIN, Zhubei City (TW); HSIEN-TA HSU, Zhubei City (TW); YI-ZHEN XIE, Zhubei City (TW); CHE-WEI LIN, Zhubei City (TW)

(21) Appl. No.: 19/372,599

(22) Filed: Oct. 29, 2025

Related U.S. Application Data
(60) Provisional application No. 63/713,204, filed on Oct. 29, 2024.

(51) Int. Cl. G01R 1/067; G01R 1/073; G01R 31/26

(52) U.S. Cl. CPC G01R 1/0675; G01R 1/06716; G01R 1/06772; G01R 1/07314; G01R 31/2601

(57) ABSTRACT

A probe head includes a plurality of probes, an upper guide plate, and a lower guide plate. Each probe has a tip, a tail, and a body. The tip is configured to contact an electronic device under test. The body extends along a longitudinal axis between the tail and the tip and has a multilayer structure including a plurality of probe arms and at least one slit. The probe arms are arranged in a widthwise direction and separated by the at least one slit penetrating the body in a thickness direction. The probe arms converge at upper and lower key portions, which respectively correspond to guide holes of the upper and lower guide plates for accommodating the probe. At least one of the upper and lower key portions is located within the corresponding guide hole.

### CROSS-REFERENCE TO RELATED APPLICATIONS

This application claims priority to U.S. Provisional Application No. 63/713,204 filed on Oct. 29, 2024, the contents of which are incorporated herein by reference in its entirety.

### BACKGROUND OF THE INVENTION

The present invention relates to a probe system, a probe card, a probe head, and method for testing electronic device under test (DUT) integrated on a semiconductor wafer, as well as to a DUT tested by the probe card. More particularly, the present invention relates to a probe system, a probe card, and a probe head configured to reduce the rigidity of probes so as to enable the probes to meet high-frequency/high-speed test requirements and high-current test requirements, as well as to a method for testing the electronic DUT using the probe system and to the DUT tested thereby.

A probe card is a tool for testing the electrical characteristics of semiconductor wafers or packaged devices. In general, it may at least include a probe head, a space transformer, and a circuit board. The probe head may include a plurality of probes, each configured to contact a pad of an electronic DUT integrated in a semiconductor wafer to test the electrical performance of the DUT. The type of pad may vary depending on the type of contact area formed on the probe tip. For example, a pad having a bump-type structure corresponds to a blunt-type contact area, whereas a pad having a flat-type structure corresponds to a sharp-type contact area.

During testing, the probe and the DUT move relative to each other along a longitudinal axis (i.e., the Z-axis) by a distance, namely a vertical movement of the probe (also referred to as an overdrive or overtravel). Typically, this movement is achieved by a wafer chuck carrying the DUT and moving upward from the contact height toward the probes, such that the contact area of the probe tip comes into contact with and presses against the pad of the DUT. This operation ensures sufficient mechanical contact between the probe tip and the pad and establishes a reliable electrical connection between the probe and the DUT. However, when the contact area of the probe tip presses the pad of the DUT in the above-described manner, differences in rigidity among probes will affect the contact force applied to the pad of the DUT under the same specified displacement (i.e., the same vertical movement). Specifically, the higher the overall rigidity of a probe, the greater the contact force exerted on the pad under the same displacement. A larger contact force applied by the probe contact area on the pad of the DUT may result in greater wear or damage either to the pad or to the probe itself (i.e., the contact area of the probe tip). Accordingly, the rigidity of the probe clearly influences the likelihood of excessive or undesired wear on the pad of the DUT and/or the probe itself during testing.

In recent years, the demand for high-frequency and high-speed testing of electronic devices under test has been rapidly increasing. As the data transmission rate during testing rises (e.g., from 50-60 gigabits per second (Gbps) to over 100 Gbps), the impedance matching between the overall probe head and the DUT becomes increasingly critical for stable high-speed signal transmission. When the impedance of the test path (i.e., the signal transmission path) is mismatched, the resulting return loss becomes significant. To meet high-frequency and high-speed test requirements, probe designers aim to shorten the probe length to facilitate high-speed and high-frequency signal transmission. In addition to such requirements, high-current testing has also become an increasingly important direction in the relevant field. To meet high-current testing needs, probe designers often seek to increase the probe thickness to support large current conduction. However, both shortening the probe length and increasing the probe thickness inherently increase the overall rigidity of the probe. As mentioned earlier, greater probe rigidity increases the likelihood of excessive or improper stress being applied to the DUT pad during testing, potentially causing damage not only to the pad but also to other parts of the DUT. As a corresponding solution, the prior arts have introduced manufacturing processes that form contact probes with multi-layer structures (i.e., having multiple probe arms and a slit between the arms) rather than producing solid, rod-shaped probe bodies. Such a configuration (i.e., a probe body having an opening, hole, or slot) effectively reduces the rigidity of the contact probe, thereby reducing the pressure applied to the corresponding pad while maintaining sufficient elasticity of the probe body.

### SUMMARY OF THE INVENTION

The foregoing prior art provides approaches for reducing the rigidity of contact probes. However, once the probe body of a contact probe adopts a slitted structure, the size, length, and position of the slit will significantly affect the contact force, stress distribution, structural strength, and lateral deflection tendency of the contact probe. In particular, the portion extending from the end of the hollow slot (slit) within the probe body to the adjacent contact end, i.e., the probe tip or the probe tail, hereinafter referred to as a key portion, often becomes a stress concentration region of the entire probe. When the probe is subjected to overdrive (OD) displacement and pressing during testing, the key portion is highly susceptible to structural weakness caused by stress concentration, resulting in fatigue damage or even fracture of the probe after repeated testing cycles.

In view of the foregoing, there is an urgent need in the relevant technical field for an improved vertical contact probe structure and a corresponding guide plate configuration that can effectively suppress stress concentration and fracture risk at the key portions while maintaining appropriate elasticity and reduced contact force. At the same time, such an improved structure should also accommodate high-frequency or high-speed signal transmission and high-current test requirements, thereby enhancing the durability and electrical stability of the probe under repeated test cycles.

To at least address the aforementioned technical problems, the present invention provides a probe head for performing functional testing on an electronic device under test integrated in a semiconductor wafer. The probe head may include a plurality of vertical contact probes, an upper guide plate unit, and a lower guide plate unit. Each vertical contact probe may include a probe tip, a probe tail, and a probe body. The probe tip may be used to contact a corresponding contact pad on the electronic device under test during testing. The probe body may extend along a longitudinal development axis between the probe tail and the probe tip. In each vertical contact probe, the probe body may have a width in a width direction and a thickness in a thickness direction. The width direction may be substantially perpendicular to the thickness direction and also substantially perpendicular to the longitudinal development axis. The probe body may have a multilayer structure that includes a plurality of probe arms and at least one slit. The plurality of probe arms may be arranged along the width direction and separated by the at least one slit, and the at least one slit may extend through the probe body along the thickness direction. The plurality of probe arms may converge at an upper key portion and a lower key portion. The upper key portion and the lower key portion may respectively have corresponding guide holes in the upper guide plate unit and the lower guide plate unit for accommodating the vertical contact probe, and at least one of the upper key portion and the lower key portion is located within its corresponding guide hole.

To at least address the aforementioned technical problems, the present invention further provides a probe card for performing functional testing on an electronic device under test integrated in a semiconductor wafer. The probe card may include a circuit board, a space transformer disposed on the circuit board, and the probe head described above. The probe head may be disposed on a side of the space transformer opposite to the circuit board, and the probe tails of the probes in the probe head are configured to be electrically connected to the space transformer.

To at least address the aforementioned technical problems, the present invention further provides a probe system for performing functional testing on an electronic device under test integrated in a semiconductor wafer. The probe system may include a wafer chuck for supporting the semiconductor wafer. The probe system may further include a test apparatus configured to be electrically connected to the electronic device under test and to establish an electrical testing procedure. The probe system may further include the probe card described above, which is disposed on the test apparatus.

To at least address the aforementioned technical problems, the present invention further provides an electronic device under test. The electronic device under test performs a high-frequency testing procedure using the probe card described above. The high-frequency testing procedure employs a high-frequency signal and is a loopback testing procedure.

In summary, the probe system, probe card, and probe head provided by the present invention, through the multilayer structure of the probes, not only reduce the overall rigidity of the probes so that the contact force applied by the probe tip on the pad of the electronic device under test during testing is alleviated, but also minimize the stress applied to the key portions during testing through the relative positional configuration between the guide plates and the probes. As a result, the key portions bear relatively lower bending stress, or even no bending stress, compared with other portions of the probe body. Accordingly, the present invention effectively reduces the risk of probe fracture under applied stress.

The above content is not intended to limit the present invention, but only briefly describes the technical problems that can be solved by the present invention, the technical means that can be adopted, and the technical effects that can be achieved, so that a person having ordinary skill in the art can have a preliminary understanding of the present invention. The embodiments of the present invention will be described below in conjunction with the drawings.

### BRIEF DESCRIPTION OF DRAWINGS

As shown below:

FIG. 1A illustrates a wafer test system including a probe card, a probe head, and probes according to one or more embodiments of the present invention.

FIG. 1B illustrates a side view structure of a vertical contact probe according to one or more embodiments of the present invention.

FIG. 1C illustrates a cross-sectional view of a probe body taken from FIG. 1B.

FIGS. 2A to 2H illustrate side view structures of probes and guide plate units during testing according to multiple embodiments of the present invention.

FIG. 3A illustrates another type of side view structure of a vertical contact probe according to one or more embodiments of the present invention.

FIG. 3B illustrates a partial structure of the vertical contact probe shown in FIG. 3A.

FIG. 3C illustrates a partially enlarged view of the probe body of a vertical contact probe during testing according to one or more embodiments of the present invention.

FIG. 3D illustrates a further enlarged view of the bump structures shown in FIG. 3C.

FIG. 4 illustrates various cross-sectional views of probe bodies according to one or more embodiments of the present invention.

FIG. 5 illustrates various side view structures of probes according to one or more embodiments of the present invention.

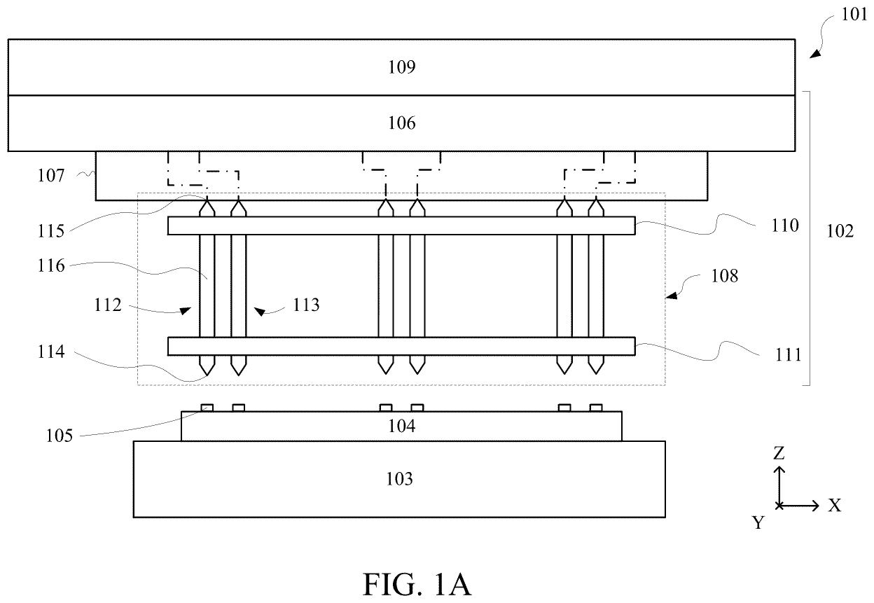

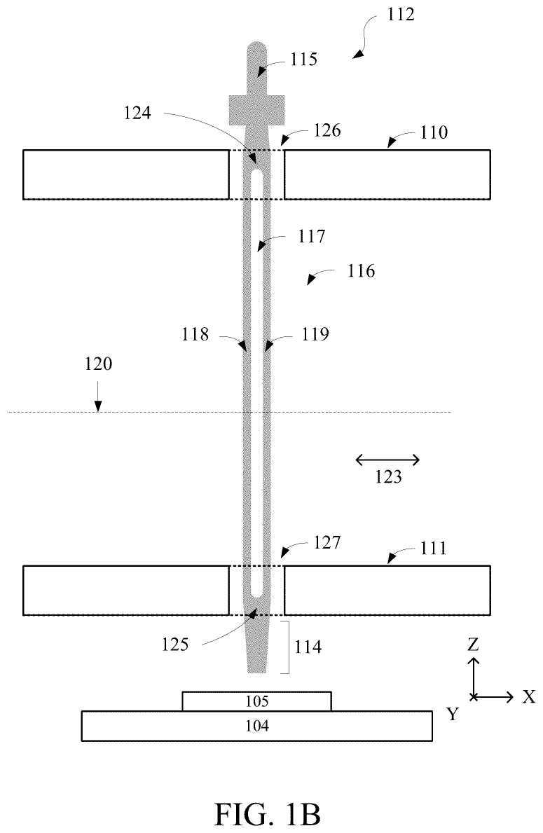

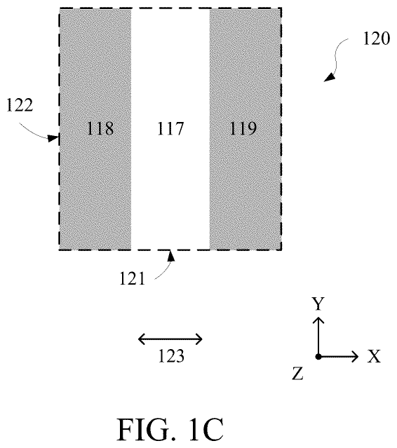

The contents shown in FIGS. 1A to 5 are merely examples provided for illustrating embodiments of the present invention and are not intended to limit the scope of the invention.

### DETAILED DESCRIPTION OF THE INVENTION

In the following description, the present invention will be described below through multiple embodiments, but these embodiments are not intended to limit the present invention to any specific environment, applications, structures, processes or situations. The attached drawings are proposed to assist in the description of the embodiments, but limit the protection scope of the present invention. In the attached drawings, elements which are not directly related to this invention are omitted from depiction. Dimensions and dimensional relationships among individual elements in the attached drawings are only exemplary examples and are not intended to limit this invention. Unless stated particularly, same (or similar) element numerals may correspond to same (or similar) elements in the following description without inconsistency with this invention. If it can be implemented, the number of each element described below may be one or more unless otherwise specified.

The terminology used herein is for the purpose of describing the embodiments only and is not intended to limit the present invention. The singular forms “a” and “an” are intended to include the plural forms as well, unless the context clearly indicates otherwise. The terms “comprises,” “comprising,” “includes,” “including,” etc., specify the presence of the stated features, integers, operations, elements, and/or components, but do not preclude the presence or addition of one or more other features, integers, operations, elements, components, and/or groups thereof. The term “and/or” includes any and all combinations of one or more of the associated listed items. Although the terms “first”, “second” and “third” etc., may be used herein to describe various elements, these elements should not be limited by these terms. These terms are merely used to distinguish one element from another element. Thus, for example, a “first” element could also be termed a “second” element, and vice versa, without departing from the spirit and scope of this invention.

Referring to FIG. 1A, a probe system 101 according to one or more embodiments of the present invention is illustrated. The probe system 101 may include at least a probe card 102 and a wafer chuck 103. The probe card 102 may be used to electrically connect to and/or physically contact an electronic device under test 104, and to test the electrical performance of the electronic device under test 104. The probe card 102 may be configured to perform testing on the electronic device under test 104, which may be a semiconductor wafer. The wafer chuck 103 may be used to support the electronic device under test 104 so that the probe card 102 may conduct inspection or measurement on the electronic device under test 104. The electronic device under test 104 may include one or more contact pads (e.g., contact pad 105 shown in FIG. 1A) such that the contact region of each probe is configured to contact one of the one or more contact pads of the electronic device under test 104 during testing (in FIG. 1A, each probe's contact region is shown as not yet in contact with the corresponding contact pad).

The probe card 102 may include a circuit board 106, a space transformer 107, and a probe head 108. The space transformer 107 may be disposed on the circuit board 106, and the probe head 108 may be disposed on the space transformer 107. The probe head 108 may generally include a plurality of probes and at least one guide plate. One end of each probe may be electrically connected to the circuit board 106 through the space transformer 107, while the other end may contact a contact pad (e.g., a metal pad or conductive bump) on the electronic device under test 104 during testing. It should be noted that the description that the space transformer 107 is disposed on the circuit board 106 is based merely on their relative conventional size relationship and does not necessarily limit the space transformer 107 to being physically located above the circuit board 106 in a spatial sense.

A test equipment 109 may conduct various test procedures on the electronic device under test or communicate test information through the probe card 102. The test equipment 109 may be, for example, a test head of a tester. In certain testing modes, a loopback test procedure may be included, in which the electronic device under test 104 itself generates a required high-frequency test signal. The signal passes through the probe card 102 and is then transmitted back to the electronic device under test 104, and further being analyzed to determine whether the electronic device under test 104 operates properly.

The circuit board 106 may include a wafer side and a tester side. The wafer side and the tester side of the circuit board 106 are oppositely arranged, and the tester side of the circuit board 106 is provided for connection with the test equipment. In the present embodiment, when the probe card 102 is used in the test equipment 109, the wafer side may be a lower surface of the circuit board 106, which may face the space transformer 107 and/or the electronic device under test 104, and the tester side may be an upper surface of the circuit board 106, which may face away from the electronic device under test 104 and/or face the test equipment 109. In the present embodiment, the circuit board 106 is implemented as a general printed circuit board having a top surface, a bottom surface, and various signal lines located therein. Contact pads electrically connected to the signal lines are formed on the top and bottom surfaces. The pogo pins of the test equipment contact the contact pads on the top surface of the circuit board 106. The test signals from the test equipment may be transmitted through the signal lines to the bottom surface of the circuit board 106.

The space transformer 107 may also include a wafer side and a tester side. It should be noted that the space transformer 107 may be formed of a multilayer circuit board. The tester side of the space transformer 107 may be connected to the wafer side of the circuit board 106. In the present embodiment, when the probe card 102 is used in the test equipment 109, the wafer side of the space transformer 107 may be a lower surface thereof, which may face the probe head 108 and/or the electronic device under test 104, while the tester side may be an upper surface thereof, which may face away from the electronic device under test 104, may face the circuit board 106, and/or may face the test equipment 109. In the present embodiment, the space transformer 107 may include a multilayer organic (MLO) substrate or a multilayer ceramic (MLC) substrate, and the material may be adjusted according to actual requirements, which is not limited by the present invention. The space transformer 107 has various internal signal lines and contact pads formed on its top and bottom surfaces that are electrically connected to the internal signal lines. The pitch between the contact pads on the top surface is greater than that between the contact pads on the bottom surface. The space transformer 107 is mechanically and electrically connected to the wafer side of the circuit board 106, namely to the bottom surface of the circuit board 106, and is located below the circuit board 106, so that the contact pads on the top surface of the space transformer 107 are electrically connected to the contact pads on the bottom surface of the circuit board 106, thereby electrically connecting the signal lines within the space transformer 107 with those within the circuit board 106. It should be further noted that the space transformer 107 and the circuit board 106 may also be mechanically and/or electrically connected indirectly through another interposer, such as a spacer board, arranged between them.

The probe head 108 may be mechanically and/or electrically connected to the wafer side of the space transformer 107. As shown in FIG. 1, the probe head 108 may include an upper guide plate unit 110, a lower guide plate unit 111, and a plurality of vertical contact probes (e.g., the vertical contact probes 112 and 113 shown in FIG. 1). Each vertical contact probe may physically contact the electronic device under test 104. The upper guide plate unit 110 may include at least one upper guide plate, and each of the at least one upper guide plate may be provided with a plurality of upper guide holes. The lower guide plate unit 111 may include at least one lower guide plate, and each of the at least one lower guide plate may be provided with a plurality of lower guide holes. The upper guide plate unit 110 and the lower guide plate unit 111 may be disposed opposite to each other along a longitudinal axis (e.g., substantially along the coordinate axis Z in the local coordinate system of FIG. 1, hereinafter referred to as the “Z axis”). Each probe may pass through one corresponding upper guide hole among the plurality of upper guide holes and one corresponding lower guide hole among the plurality of lower guide holes.

The vertical contact probes are typically made of special metals having good electrical and mechanical properties. By pressing the probe head 108 against the electronic device under test 104, reliable contact between the probes and the contact pads of the electronic device under test 104 can be ensured. During the pressing contact, each probe may slide within the corresponding guide holes of the upper and lower guide plate units, and may bend within the air gap between the upper and lower guide plate units.

According to certain embodiments of the present invention, each vertical contact probe included in the probe head 108 may be a probe commonly referred to in the art as a “buckling beam” probe. The probe body of such a probe may have a constant cross section along its entire length (e.g., a substantially rectangular shape, preferably a square or rectangular shape), in which the probe body is configured to bend and/or stretch at a position substantially located at the center, thereby deforming during testing of the electronic device under test 104. However, in some other embodiments, each probe does not necessarily have a constant cross section along its entire length.

The term “substantially rectangular” as used herein refers to a rectangular shape and other actual results that may occur when manufacturing a probe body intended to have a rectangular cross section, such as a trapezoidal shape. More specifically, it should be understood by those skilled in the art that even if the equipment used for manufacturing the probes is designed to produce a probe having a rectangular cross section, the actual manufactured probe cross section may have certain tolerances or fabrication deviations, such that the cross section of the probe body may not be a geometrically perfect rectangle in some embodiments.

The vertical contact probes applicable to the present invention may at least include straight-type probes, such as forming wire (FW) probes or MEMS wire (MW) probes.

As shown in FIG. 1A, each vertical contact probe may include a probe tip (e.g., the probe tip 114 included in the vertical contact probe 112), a probe tail (e.g., the probe tail 115 included in the vertical contact probe 112), and a probe body (e.g., the probe body 116 included in the vertical contact probe 112) located between the probe tip and the probe tail. The probe tip may terminate at a contact region and may be configured to be adjacent to a corresponding contact pad of the electronic device under test 104 integrated in a semiconductor wafer (e.g., in FIG. 1, the probe tip 114 is configured to be adjacent to the contact pad 105 of the electronic device under test 104). The probe tail of each probe may pass through a guide hole in the upper guide plate unit 110 to be electrically connected to the space transformer 107. The probe tail may terminate at a contact end and may be configured to be adjacent to a contact pad of the space transformer 107 (not shown in the figure). The probe body may extend substantially along the longitudinal axis between the probe tip and the probe tail. Each probe tip may be used for electrical contact with the electronic device under test 104. Each probe may be configured to establish electrical and/or physical communication with a corresponding contact pad of the electronic device under test 104. The term “communication” herein refers to the configuration in which the probe transmits a test signal from the probe card 102 to the electronic device under test 104, and/or receives a signal from the electronic device under test 104.

Many embodiments of the present invention primarily relate to various implementations of probe structures and guide plate configurations, and extend to the probe head, probe card, and probe system including such probe structures. It should be noted, however, that although the probe structures in different embodiments of the present invention may vary slightly, the plurality of vertical contact probes included in the probe head of each embodiment may collectively include at least one vertical contact probe pair (e.g., the probe pair formed by the vertical contact probes 112 and 113 in FIG. 1). In some embodiments, each vertical contact probe pair may be used to transmit a set of differential signals, and such a vertical contact probe pair may therefore also be referred to as a “differential pair.” In the preferred embodiments of the present invention, the differential pair may use two single-ended signal lines (e.g., a P-line and an N-line) respectively connected to TX+and RX+, and to TX− and RX−, to transmit signals simultaneously, the two signals having identical voltage amplitudes but opposite phases.

FIG. 1B illustrates, using the vertical contact probe 112 as an example, a structural example of the probes included in the probe head 108. Those skilled in the art can understand, based on the description of the vertical contact probe 112, the possible structures of the probes within the probe head 108. Referring first to FIG. 1B, which shows a side view of the vertical contact probe 112 from a perspective similar to that of FIG. 1A, the probe body 116 extends along the longitudinal axis (Z-axis) and may include a slit 117. The slit 117 may extend along the longitudinal axis and pass through a central point of the probe body 116 in the longitudinal direction (in other words, the length of the slit 117 along the longitudinal axis may account for more than half of the length of the probe body 116), thereby dividing the probe body 116 into two probe arms, namely a probe arm 118 and a probe arm 119.

The probe body 116 may have a cross-section 120 that is perpendicular to the longitudinal axis (Z-axis). Referring to both FIG. 1B and FIG. 1C, the cross-section 120 has a width side 121 and a thickness side 122. The probe arms 118 and 119 are arranged along the width side 121. The slit 117 is located between the probe arms 118 and 119. In some embodiments, the probe arms 118 and 119 may be symmetrically arranged about the slit 117.

The width side 121 may be parallel to a bending direction 123 of the probe arms 118 and 119 when the vertical contact probe 112 contacts the electronic device under test 104. In some embodiments, the bending direction 123 may be parallel to the width side 121, as jointly illustrated in FIGS. 1B and 1C. Furthermore, FIG. 1B illustrates the bending direction 123 as being parallel to the X-axis direction, while FIG. 1C further shows that the width side 121 is also parallel to the X-axis direction. Accordingly, during testing, the probe arms 118 and 119 may bend together toward either the right or left side in FIG. 1B, i.e., toward the positive or negative direction of the X-axis.

In some embodiments, a thickness of the probe body 116 may be greater than or equal to a width of the probe body 116. The width may be represented by the width side 121, and the thickness may be represented by the thickness side 122. For a multilayer-structure probe in which the probe body thickness is greater than or equal to its width, the rigidity-weakening effect is significantly superior to that of a multilayer-structure probe in which the width is greater than the thickness. When the buckling direction of the probe is along the width side (e.g., as shown in FIG. 1B), the weakening effect becomes even more pronounced.

Referring again to FIG. 1B, the probe arms 118 and 119 may converge at an upper key portion 124 and a lower key portion 125, which correspond respectively to a section extending from an upper end of the slit 117 toward the probe tail 115, and a section extending from a lower end of the slit 117 toward the probe tip 114. It should be noted that the term “converge” as used herein may refer to an implementation in which the probe arms are geometrically positioned so closely that they appear nearly integral, and may also encompass configurations in which the probe arms are merged into a single structure or formed integrally within such a section, rather than merely being geometrically adjacent.

The upper key portion 124 and the lower key portion 125 may correspond respectively to a guide hole 126 in the upper guide plate unit 110 and a guide hole 127 in the lower guide plate unit 111, which accommodate the vertical contact probe 112. The upper key portion 124 may be positioned within the guide hole 126 of the upper guide plate unit 110, and/or the lower key portion 125 may be positioned within the guide hole 127 of the lower guide plate unit 111, so that the key portions bear relatively low bending stress or even no bending stress compared with other portions of the probe body.

For a vertical contact probe, the probe length needs to have a certain dimension, for example but not limited to about 3 mm to 7 mm, in order to meet the requirements for large and small offsets during testing. When the probe length increases due to such offset requirements, the slit formed in the probe body may cause the key portions (i.e., the regions where the multiple probe arms converge) to exhibit arm bifurcation phenomena, and may also introduce stress concentration issues.

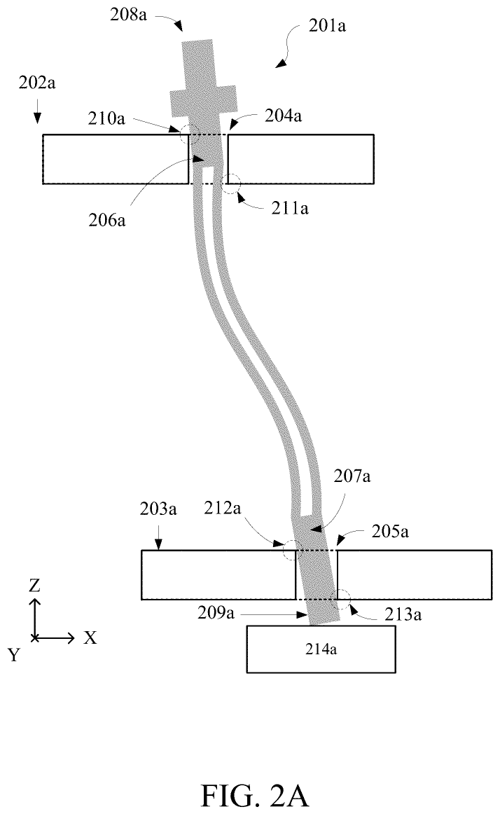

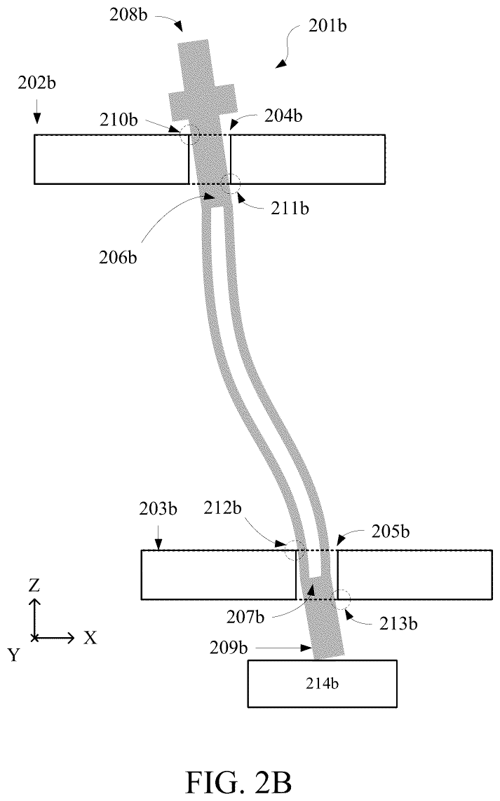

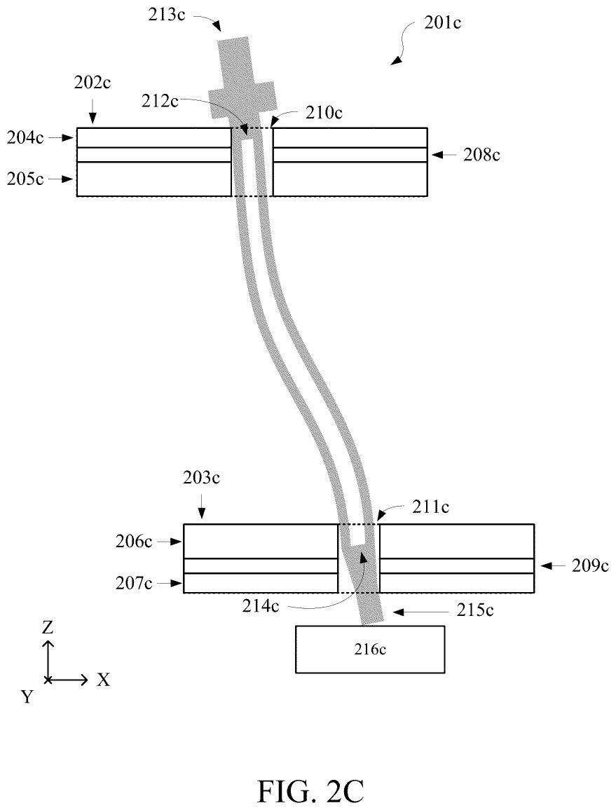

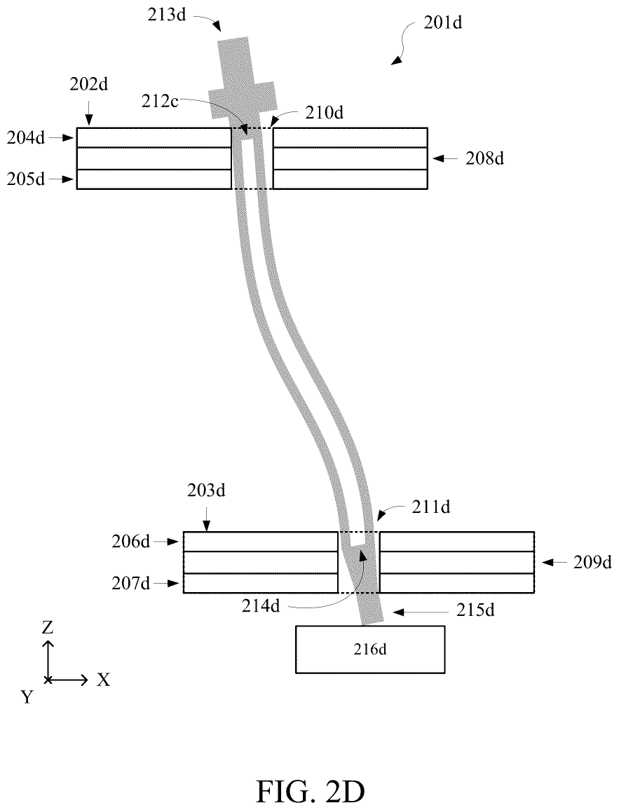

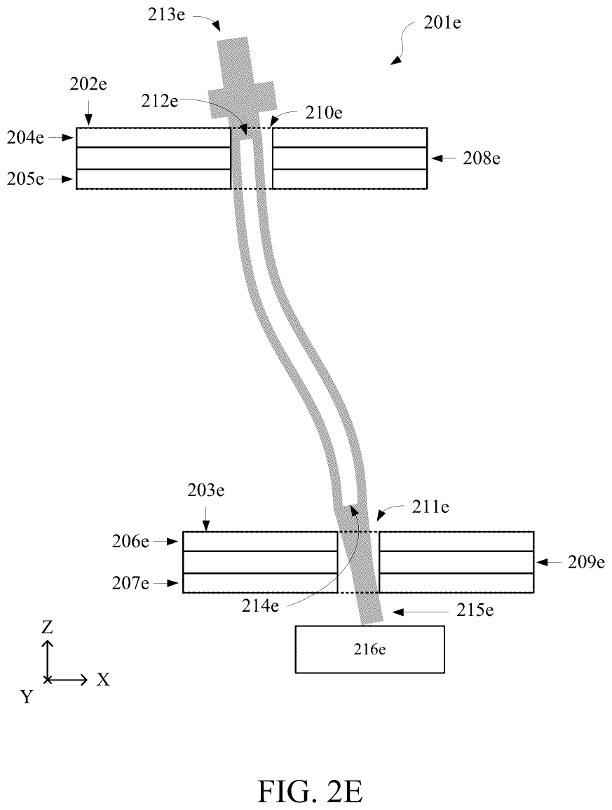

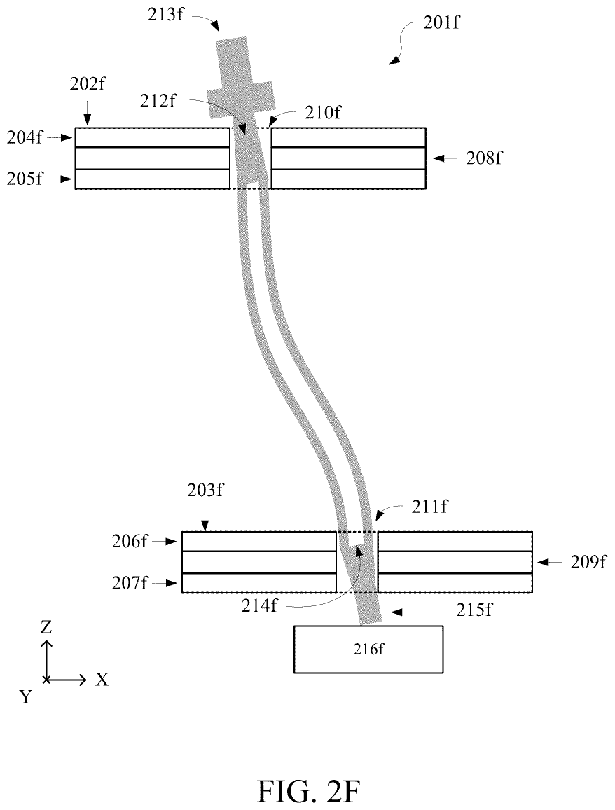

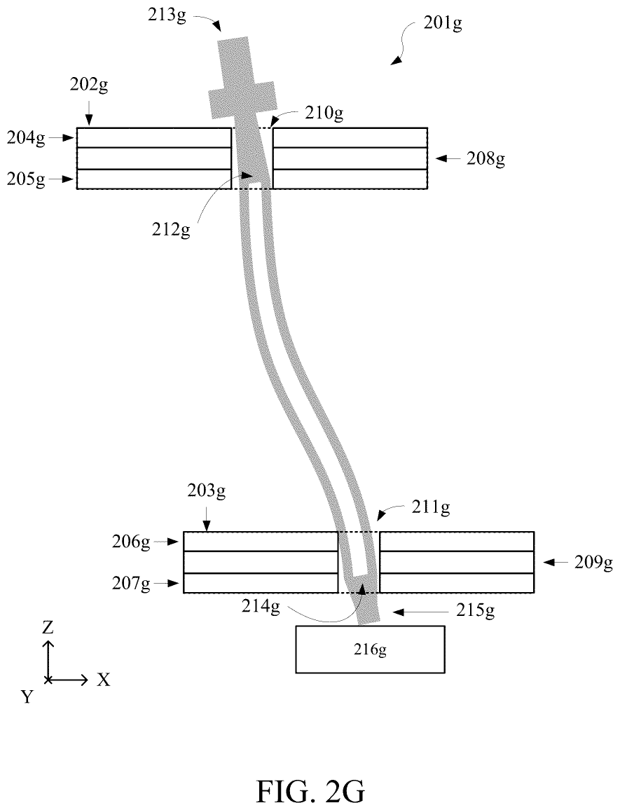

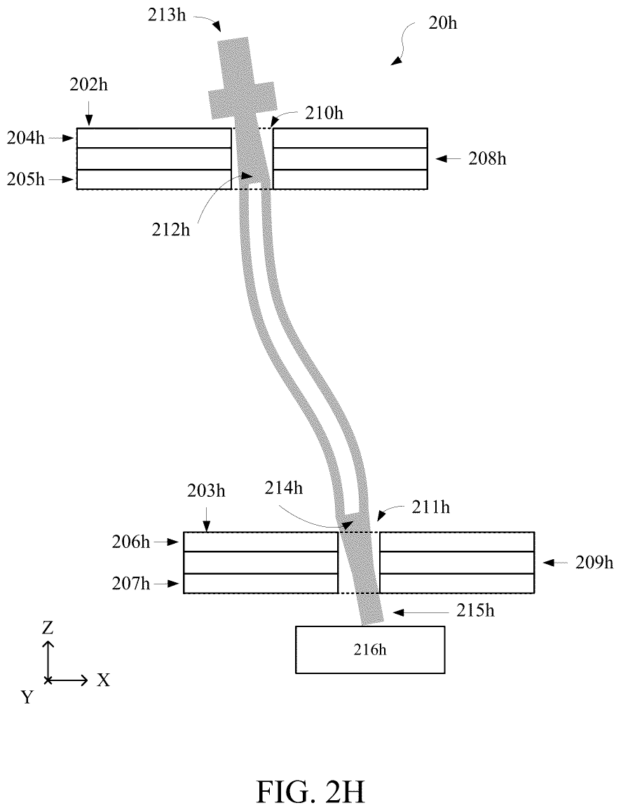

Furthermore, at the key portions, the probe arms rejoin into a single structure at the ends of the slit. These regions may simultaneously bear longitudinal compression forces (from overdrive pressure), bending stresses (caused by guide plate misalignment or lateral deflection), and concentrated stresses (due to the slit-end effect). Consequently, the converging regions (key portions) may become the structural bottlenecks (the weakest points) of the overall probe, where fatigue cracks or fractures are likely to occur. Accordingly, in many embodiments of the present invention, at least one of the upper and lower key portions is positioned within the guide hole, and in some embodiments, at least one of them abuts against the wall of the corresponding guide hole, thereby achieving a restraining and reinforcing effect for the key portion. In particular, when significant misalignment occurs in the width direction (i.e., along the X-axis direction shown in the figures), this configuration can effectively reduce the risk of bifurcation and damage at the key portions. Relevant details are illustrated in FIGS. 2A to 2H.

FIGS. 2A to 2H show side-view structures of the vertical contact probe and the guide plate units according to multiple embodiments of the present invention when the probe undergoes elastic deformation under an overdrive displacement and pressure during testing. Referring first to FIG. 2A, it illustrates a vertical contact probe 201a, an upper guide plate unit 202a, and a lower guide plate unit 203a. The upper guide plate unit 202a and the lower guide plate unit 203a are respectively provided with a guide hole 204a and a guide hole 205a, and the vertical contact probe 201a may pass through the guide holes 204a and 205a along the longitudinal axis.

The probe body of the vertical contact probe 201a may include an upper key portion 206a (i.e., a section extending from the end region of the slit in the probe body toward the probe tail 208a) and a lower key portion 207a (i.e., a section extending from the end region of the slit in the probe body toward the probe tip 209a). The upper key portion 206a (particularly the end region of the slit in the probe body) may be disposed within the guide hole 204a, while the lower key portion 207a (particularly the end region of the slit in the probe body) may be located outside the guide hole 205a, in the region between the upper guide plate unit 202a and the lower guide plate unit 203a. In this configuration, the vertical contact probe 201a may abut the upper guide plate unit 202a at positions 210a and 211a, where one side of the upper key portion 206a (e.g., the left side as shown in FIG. 2A) may abut the wall of the guide hole 204a. At the same time, the vertical contact probe 201a may abut the lower guide plate unit 203a at positions 212a and 213a.

During testing, when the upper guide plate unit and the lower guide plate unit are relatively misaligned and the vertical contact probe 201a is further subjected to an overdrive pressure after the probe tip 209a contacts the contact pad 214a of the electronic device under test, the potential arm-bifurcation phenomenon at the upper key portion 206a can be effectively suppressed because the upper key portion 206a is positioned within the guide hole 204a. The abutting action of the wall of the guide hole 204a on the upper key portion 206a can further enhance the structural strength of this region and reduce the risk of fracture. As for the lower key portion 207a, since it is disposed in the region between the upper guide plate unit 202a and the lower guide plate unit 203a, the relatively fragile part of the probe body (i.e., the end region of the slit in the probe body) can be prevented from bearing major stress, and instead the portions located at positions 212a and 213a bear the corresponding load.

Referring to FIG. 2B, it illustrates a vertical contact probe 201b, an upper guide plate unit 202b, and a lower guide plate unit 203b. The upper guide plate unit 202b and the lower guide plate unit 203b are respectively provided with a guide hole 204b and a guide hole 205b, and the vertical contact probe 201b may pass through the guide holes 204b and 205b along the longitudinal axis.

The probe body of the vertical contact probe 201b may include an upper key portion 206b (i.e., a section extending from the end region of the slit in the probe body toward the probe tail 208b) and a lower key portion 207b (i.e., a section extending from the end region of the slit in the probe body toward the probe tip 209b). The upper key portion 206b (particularly the end region of the slit in the probe body) is disposed outside the guide hole 204b, in the region between the upper guide plate unit 202b and the lower guide plate unit 203b, while the lower key portion 207b (particularly the end region of the slit in the probe body) is disposed within the guide hole 205b. In this configuration, the vertical contact probe 201b may abut the upper guide plate unit 202b at positions 210b and 211b, and simultaneously abut the lower guide plate unit 203b at positions 212b and 213b.

During testing, when the upper guide plate unit 202b and the lower guide plate unit 203b are relatively misaligned and the vertical contact probe 201b is subjected to an overdrive displacement after the probe tip 209b contacts the contact pad 214b of the electronic device under test, the potential arm-bifurcation phenomenon at the lower key portion 207b can be effectively suppressed because the lower key portion 207b is positioned within the guide hole 205b. The abutting action of the wall of the guide hole 205b on the lower key portion 207b can also further enhance the structural strength of this region and reduce the risk of fracture. As for the upper key portion 206b, since it is disposed in the region between the upper guide plate unit 202b and the lower guide plate unit 203b, the relatively fragile part of the probe body (i.e., the end region of the slit in the probe body) can be prevented from bearing major stress, and instead the portions located at positions 210b and 211b bear the corresponding load.

Referring to FIG. 2C, it illustrates a vertical contact probe 201c, an upper guide plate unit 202c, and a lower guide plate unit 203c. The upper guide plate unit 202c and the lower guide plate unit 203c may each have a multilayer structure configuration. As illustrated in FIG. 2C, the upper guide plate unit 202c may include an outer guide plate 204c and an inner guide plate 205c, while the lower guide plate unit 203c may include an inner guide plate 206c and an outer guide plate 207c. A middle guide plate 208c may be provided between the outer guide plate 204c and the inner guide plate 205c, and another middle guide plate 209c may be provided between the outer guide plate 207c and the inner guide plate 206c. Each of the guide plates may have the same or different thicknesses (in the Z-axis direction) and can be used to adjust the overall thickness of the guide plate units to accommodate different probe lengths or to control the amount of probe deflection.

The multilayer guide plate units are formed by bonding the inner and outer guide plates together into an integral structure. In some embodiments, the plurality of layers may have different thicknesses (e.g., in FIG. 2C, the inner layers are thicker), thereby adjusting the fixing effect of the probe at different longitudinal sections. Such an arrangement of inner and outer layers with unequal thickness can enhance the retention of specific portions of the probe where lateral deflection is relatively large or provide additional protection to regions subjected to the greatest stress. Configuring the guide plate units as assemblies of multiple guide plates also offers at least one advantage in terms of manufacturing convenience. That is, if the guide plate is excessively thick, it may become difficult or even impossible to machine the guide holes due to an excessively large depth-to-width ratio during processing.

The upper guide plate unit 202c and the lower guide plate unit 203c are respectively provided with a guide hole 210c and a guide hole 211c, and the vertical contact probe 201c may pass through the guide holes 210c and 211c along the longitudinal axis.

The probe body of the vertical contact probe 201c may include an upper key portion 212c (i.e., a section extending from the end of the slit in the probe body toward the probe tail 213c) and a lower key portion 214c (i.e., a section extending from the end of the slit in the probe body toward the probe tip 215c). In this embodiment, the upper key portion 212c is disposed within the guide hole 210c of the upper guide plate unit 202c, located at the position corresponding to the outer guide plate 204c, while the lower key portion 214c is disposed within the guide hole 211c of the lower guide plate unit 203c, located at the position corresponding to the inner guide plate 206c. This configuration allows the upper and lower key portions to be constrained by the walls of guide holes at different layer levels, thereby helping to disperse stress concentration during testing.

During testing, when the upper guide plate unit 202c and the lower guide plate unit 203c are relatively misaligned and the vertical contact probe 201c is subjected to an overdrive displacement after the probe tip 215c contacts the contact pad 216c of the electronic device under test, both end regions of the slit in the probe body can obtain reinforcement through abutting contact with the walls of the guide holes because the upper and lower key portions are respectively positioned within their corresponding guide holes. As a result, the occurrence of arm bifurcation and fatigue fracture can be effectively suppressed.

In the structure of the multilayer guide plate units, when a key portion is disposed within a guide hole and located at an outer layer position, it can provide early guidance and positioning as the probe approaches the outer surface of the guide plate, enabling the probe to receive preliminary constraint at the initial stage of entering the guide plate structure. This facilitates control of overall deflection and ensures spacing accuracy among probes. Conversely, when the key portion is disposed within a guide hole and located at an inner layer position, stronger structural support can be provided near the central region of the guide plate as the probe penetrates deeper, offering a more direct reinforcing effect against stress concentration under overdrive pressure. Therefore, by selecting whether the key portion corresponds to an inner or outer layer position, the configuration can be adjusted for different testing requirements. If suppression of deflection and improvement of guiding precision are prioritized, the key portion may be positioned at the outer layer. If reinforcement of the fragile slit-end regions of the probe is prioritized, the key portion may be positioned at the inner layer. In some embodiments, the upper and lower key portions may respectively occupy different layer levels in the guide holes of the upper and lower guide plate units (as illustrated in FIG. 2C), thereby achieving both deflection control and stress-reinforcement effects simultaneously.

In some embodiments, the vertical contact probe may include a reinforced section extending from the end of the slit in the probe body toward the probe tip or the probe tail (i.e., at the upper key portion or lower key portion). More specifically, as illustrated in FIG. 2C, a tapered transition region may be formed in the area extending from the lower key portion 214c to the probe tip 215c, in which the probe diameter gradually increases from the probe tip 215c (i.e., the source of contact force) toward the lower key portion 214c. This region serves as the reinforced section. The reinforced section can provide additional mechanical strength and reduce stress concentration at the region where the probe arms converge, thereby further improving the durability and contact stability of the probe under high-frequency/high-speed or high-current testing conditions. In other embodiments, the reinforced section may also be formed in the section between the probe tail and the upper key portion, as illustrated in FIG. 2F, the details of which will be described later.

Referring to FIG. 2D, it illustrates a vertical contact probe 201d, an upper guide plate unit 202d, and a lower guide plate unit 203d. The upper guide plate unit 202d and the lower guide plate unit 203d may each have a multilayer structure. As illustrated in FIG. 2D, the upper guide plate unit 202d may include an outer guide plate 204d and an inner guide plate 205d, while the lower guide plate unit 203d may include an outer guide plate 206d and an inner guide plate 207d. Middle guide plates 208d and 209d may respectively be provided between the outer and inner guide plates. Each guide plate may have the same or different thickness (in the Z-axis direction) and may be used to adjust the overall thickness of the guide plate unit to accommodate different probe lengths or to control probe deflection. Unlike FIG. 2C, in this embodiment the inner and outer guide plates of both the upper and lower guide plate units may have equal thickness, allowing structural stability and guiding performance to remain substantially uniform between the upper and lower guide plates.

The multilayer guide plate units are formed by bonding the inner and outer guide plates together into an integral structure. Because the upper and lower guide plate units are configured with inner and outer layers of equal thickness, uniform guiding characteristics are provided between the corresponding guide holes. This configuration is suitable for test applications that require consistent guiding alignment at both upper and lower ends, while also reducing local deflection or stress imbalance problems caused by layer-thickness variations.

The upper guide plate unit 202d and the lower guide plate unit 203d are respectively provided with a guide hole 210d and a guide hole 211d, and the vertical contact probe 201d may pass through the guide holes 210d and 211d along the longitudinal axis. The probe body of the vertical contact probe 201d includes an upper key portion 212d (i.e., a section extending from the end of the slit in the probe body toward the probe tail 213d) and a lower key portion 214d (i.e., a section extending from the end of the slit in the probe body toward the probe tip 215d). In this embodiment, both the upper and lower key portions 212d and 214d are disposed within the guide holes of their corresponding guide plate units at the outer-layer positions, so that the key portions at both ends are constrained and guided at the outer side of the guide plates.

During testing, when the upper guide plate unit 202d and the lower guide plate unit 203d are relatively misaligned and the vertical contact probe 201d is subjected to an overdrive displacement after the probe tip 215d contacts the contact pad 216d of the electronic device under test, the upper and lower key portions 212d and 214d are respectively constrained by the walls of their corresponding outer-layer guide holes. This allows the probe to receive deflection suppression and initial reinforcement at the early stage of entering the guide plate structure. The design helps maintain the alignment accuracy between the probe and the contact pad and reduces the risk of arm bifurcation and abrasion of the probe during repeated testing cycles.

Referring to FIG. 2E, it illustrates a vertical contact probe 201e, an upper guide plate unit 202e, and a lower guide plate unit 203e. The upper guide plate unit 202e and the lower guide plate unit 203e may each have a multilayer structure configuration. As illustrated in FIG. 2E, the upper guide plate unit 202e may include an outer guide plate 204e and an inner guide plate 205e, while the lower guide plate unit 203e may include an outer guide plate 206e and an inner guide plate 207e. Middle guide plates 208e and 209e may be provided between the outer and inner guide plates, respectively. Each guide plate may have the same or different thickness (in the Z-axis direction) and may be used to adjust the overall thickness of the guide plate unit to accommodate different probe lengths or to control probe deflection. In this embodiment, the inner and outer layers of the upper and lower guide plate units may each be designed with equal thickness, thereby providing balanced guiding rigidity and reducing deflection or stress imbalance caused by differences in layer thickness.

The upper guide plate unit 202e and the lower guide plate unit 203e are respectively provided with a guide hole 210e and a guide hole 211e, and the vertical contact probe 201e may pass through the guide holes 210e and 211e along the longitudinal axis. The probe body of the vertical contact probe 201e includes an upper key portion 212e (i.e., a section extending from the end of the slit in the probe body toward the probe tail 213e) and a lower key portion 214e (i.e., a section extending from the end of the slit in the probe body toward the probe tip 215e). In this embodiment, the upper key portion 212e is positioned within the guide hole 210e at a location corresponding to the outer guide plate 204e, while the lower key portion 214e is positioned outside the guide hole 211e, in the space between the upper guide plate unit 202e and the lower guide plate unit 203e, thereby allowing greater movement tolerance for the lower half of the probe body to accommodate different testing conditions.

During testing, when the upper guide plate unit 202e and the lower guide plate unit 203e are relatively misaligned and the vertical contact probe 201e is subjected to an overdrive displacement after the probe tip 215e contacts the contact pad 216e of the electronic device under test, the upper key portion 212e is constrained by the wall of the guide hole 210e, providing initial deflection suppression and guiding effects. Since the lower key portion 214e is located outside the guide hole 211e, it is prevented from directly bearing the relatively high stress during the testing process. As a result, localized stress concentration at the slit-end of the probe arm may be reduced, probe lifetime can be extended, and a certain degree of elastic buffering travel may be maintained under overdrive pressure.

Referring to FIG. 2F, it illustrates a vertical contact probe 201f, an upper guide plate unit 202f, and a lower guide plate unit 203f. The upper guide plate unit 202f and the lower guide plate unit 203f may each have a multilayer structure configuration. As illustrated in FIG. 2F, the upper guide plate unit 202f may include an outer guide plate 204f and an inner guide plate 205f, while the lower guide plate unit 203f may include an outer guide plate 206f and an inner guide plate 207f. Middle guide plates 208f and 209f may be provided between the outer and inner guide plates, respectively. Each guide plate may have the same or different thickness (in the Z-axis direction) and may be used to adjust the overall thickness of the guide plate units to accommodate different probe lengths or to control probe deflection. In this embodiment, the inner and outer layers of the upper and lower guide plate units may be configured with either equal or unequal thicknesses, depending on application requirements, to adjust guiding rigidity and reinforcement characteristics.

The upper guide plate unit 202f and the lower guide plate unit 203f are respectively provided with a guide hole 210f and a guide hole 211f, and the vertical contact probe 201f may pass through the guide holes 210f and 211f along the longitudinal axis. The probe body of the vertical contact probe 201f includes an upper key portion 212f (i.e., a section extending from the end of the slit in the probe body toward the probe tail 213f) and a lower key portion 214f (i.e., a section extending from the end of the slit in the probe body toward the probe tip 215f). In this embodiment, both the upper key portion 212f and the lower key portion 214f are positioned within the guide holes of their corresponding guide plate units, at locations corresponding to the inner guide plates, so that the slit-end regions at both ends of the probe body receive stronger wall constraints and reinforcement after penetrating deeper into the guide plate structure.

During testing, when the upper guide plate unit 202f and the lower guide plate unit 203f are relatively misaligned and the vertical contact probe 201f is subjected to an overdrive displacement after the probe tip 215f contacts the contact pad 216f of the electronic device under test, the upper and lower key portions 212f and 214f are respectively constrained by the walls of their corresponding inner-layer guide holes. This configuration can significantly suppress bifurcation and deflection of the probe arm ends and provide concentrated reinforcement under overdrive pressure. The arrangement is particularly suitable for high-frequency/high-speed or high-current testing conditions, enabling enhanced probe durability and structural stability while maintaining alignment accuracy.

In addition, as illustrated in FIG. 2F, a tapered transition region may be formed in the area extending from the probe tail 213f to the upper key portion 212f, in which the probe diameter gradually increases from the probe tail 213f toward the upper key portion 212f. This region serves as a reinforced section. The reinforced section can provide additional mechanical strength and reduce stress concentration at the region where the probe arms converge, thereby further improving the durability and contact stability of the probe under high-frequency/high-speed or high-current testing conditions.

Referring to FIG. 2G, it illustrates a vertical contact probe 201g, an upper guide plate unit 202g, and a lower guide plate unit 203g. The upper guide plate unit 202g and the lower guide plate unit 203g may each have a multilayer structure configuration. As illustrated in FIG. 2G, the upper guide plate unit 202g may include an outer guide plate 204g and an inner guide plate 205g, while the lower guide plate unit 203g may include an outer guide plate 206g and an inner guide plate 207g. Middle guide plates 208g and 209g may be provided between the outer and inner guide plates, respectively. Each guide plate may have the same or different thickness (in the Z-axis direction) and may be used to adjust the overall thickness of the guide plate units to accommodate different probe lengths or to control probe deflection. In this embodiment, the inner and outer guide plates of the upper and lower guide plate units may be designed with equal or unequal thicknesses, depending on application requirements, to adjust guiding rigidity and reinforcement characteristics.

The upper guide plate unit 202g and the lower guide plate unit 203g are respectively provided with a guide hole 210g and a guide hole 211g, and the vertical contact probe 201g may pass through the guide holes 210g and 211g along the longitudinal axis. The probe body of the vertical contact probe 201g includes an upper key portion 212g (i.e., a section extending from the end of the slit in the probe body toward the probe tail 213g) and a lower key portion 214g (i.e., a section extending from the end of the slit in the probe body toward the probe tip 215g). In this embodiment, the upper key portion 212g is disposed within the guide hole of the upper guide plate unit 202g at a position corresponding to the inner guide plate, while the lower key portion 214g is disposed within the guide hole of the lower guide plate unit 203g at a position corresponding to the outer guide plate. This combined configuration simultaneously provides the inner-layer reinforcement effect and the outer-layer early-guidance effect to meet the requirements for deflection control and structural strength under various testing conditions.

During testing, when the upper guide plate unit 202g and the lower guide plate unit 203g are relatively misaligned and the vertical contact probe 201g is subjected to an overdrive displacement after the probe tip 215g contacts the contact pad 216g of the electronic device under test, the upper key portion 212g is constrained by the wall of the inner-layer guide hole to strengthen the reinforcement at the probe arm ends, while the lower key portion 214g is constrained by the wall of the outer-layer guide hole to provide a guiding effect at the early stage when the probe enters the guide plate structure. This configuration achieves both deflection control and stress-concentration suppression, enhancing probe reliability and durability under high-frequency/high-speed and high-current testing conditions.

In addition, as illustrated in FIG. 2G, tapered reinforced sections may also be formed respectively in the regions extending from the upper key portion 212g to the probe tail 213g and from the lower key portion 214g to the probe tip 215g, providing additional mechanical strength and reducing stress concentration. This dual-end reinforced-section design further enhances the structural stability and durability of the probe under high-frequency/high-speed or high-current testing conditions.

Referring to FIG. 2H, it illustrates a vertical contact probe 201h, an upper guide plate unit 202h, and a lower guide plate unit 203h. The upper guide plate unit 202h and the lower guide plate unit 203h may each have a multilayer structure configuration. As illustrated in FIG. 2H, the upper guide plate unit 202h may include an outer guide plate 204h and an inner guide plate 205h, while the lower guide plate unit 203h may include an outer guide plate 206h and an inner guide plate 207h. Middle guide plates 208h and 209h may be provided between the outer and inner guide plates, respectively. Each guide plate may have the same or different thickness (in the Z-axis direction) and may be used to adjust the overall thickness of the guide plate units to accommodate different probe lengths or to control probe deflection. In this embodiment, the inner and outer guide plates of the upper and lower guide plate units may be designed with equal or unequal thicknesses depending on application requirements, so as to adjust guiding rigidity and reinforcement characteristics.

The upper guide plate unit 202h and the lower guide plate unit 203h are respectively provided with a guide hole 210h and a guide hole 211h, and the vertical contact probe 201h may pass through the guide holes 210h and 211h along the longitudinal axis. The probe body of the vertical contact probe 201h includes an upper key portion 212h (i.e., a section extending from the end of the slit in the probe body toward the probe tail 213h) and a lower key portion 214h (i.e., a section extending from the end of the slit in the probe body toward the probe tip 215h). In this embodiment, the upper key portion 212h is disposed within the guide hole of the upper guide plate unit 202h at a position corresponding to the inner-layer location, so that it obtains wall constraint after the probe penetrates deeper into the guide plate structure and provides a reinforcement effect. The lower key portion 214h is disposed outside the guide hole 211h, in the space between the upper and lower guide plate units 202h and 203h, thereby allowing greater movement tolerance of the lower key portion to accommodate different overdrive strokes and reduce direct stress concentration.

During testing, when the upper guide plate unit 202h and the lower guide plate unit 203h are relatively misaligned and the vertical contact probe 201h is subjected to an overdrive displacement after the probe tip 215h contacts the contact pad 216h of the electronic device under test, the upper key portion 212h is constrained by the wall of the inner-layer guide hole to reduce arm-end deflection and enhance reinforcement strength, while the lower key portion 214h, being located between the two guide plate units, is free from direct wall pressure and can provide elastic buffering during the test. This helps reduce fatigue fracture and improves durability.

In addition, as illustrated in FIG. 2H, tapered reinforced sections may be respectively formed in the regions extending from the upper key portion 212h to the probe tail 213h and from the lower key portion 214h to the probe tip 215h. This dual-end reinforced-section configuration can further reduce stress concentration and enhance the overall structural stability of the probe under high-frequency/high-speed and high-current testing conditions.

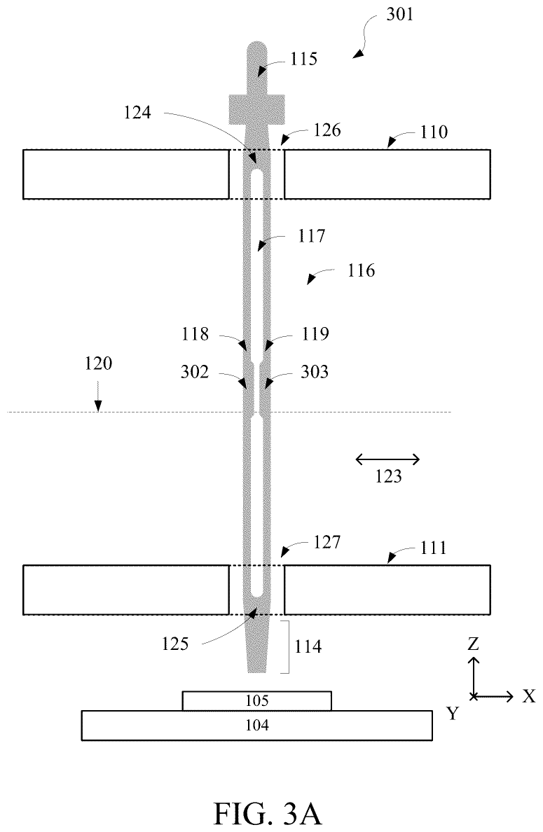

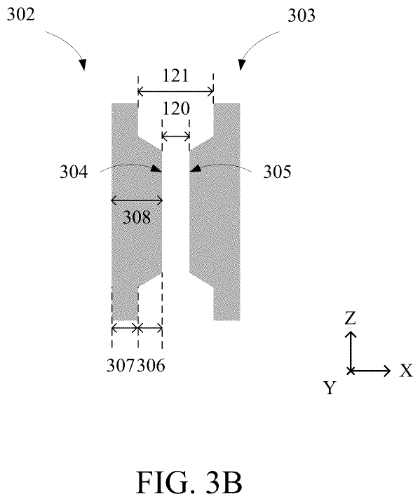

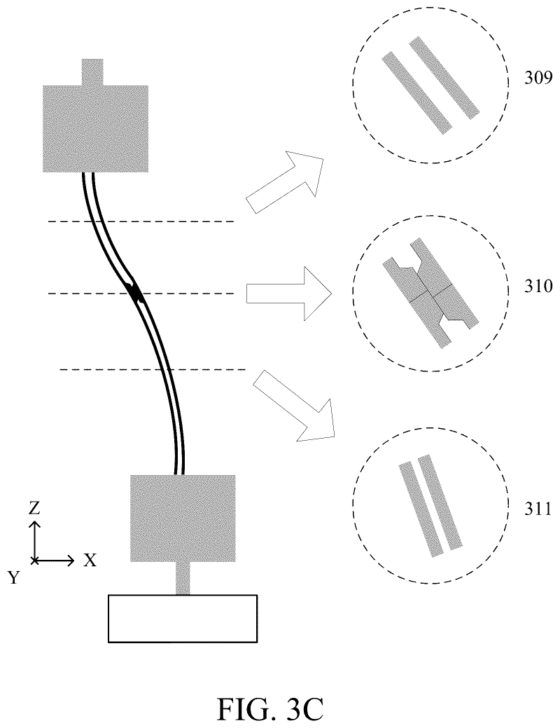

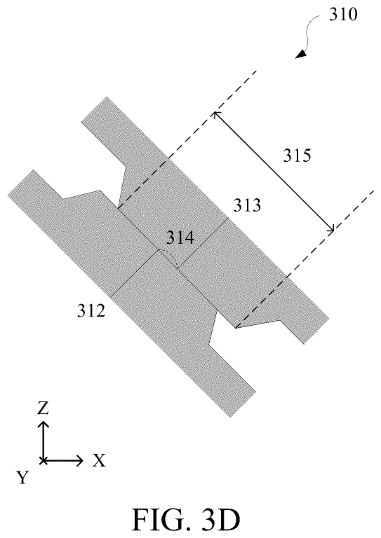

FIG. 3A illustrates another side-view structure of a vertical contact probe according to one or more embodiments of the present invention. More specifically, referring collectively to FIG. 1B and FIG. 3A, FIG. 3A shows a vertical contact probe 301, which is based on the vertical contact probe 112 illustrated in FIG. 1B, wherein two adjacent probe arms 118 and 119 of the probe body 116 are respectively provided with bump structures within the slit 117, namely a bump structure 302 and a bump structure 303.

The bump structures serve as contact points where the two probe arms support each other during testing, thereby improving stability during buckling movement of the probe body and maintaining a consistent bending direction. The bump structure 302 and the bump structure 303 are respectively formed by portions of the inner sidewalls of the probe arms 118 and 119 that protrude toward the central axis of the slit 117, and they are arranged opposite to each other. When the probe body 116 is in a non-buckled state (i.e., without deformation caused by applied force), the bump structures 302 and 303 are positioned opposite to each other within the slit 117 and are separated from each other in the width direction (i.e., along the positive or negative X-axis direction in the figure). They are located between the upper key portion 124 and the lower key portion 125 along the longitudinal axis (i.e., the Z-axis direction in the figure).

The spacing between the bump structure 302 and the bump structure 303 in the width direction may be smaller than the spacing between the probe arms 118 and 119 in the same direction.

In some embodiments, when viewed from the thickness direction (i.e., the positive Y-axis direction in FIG. 3A, corresponding to the perspective illustrated in FIG. 3A), the bump structures on each probe (e.g., the bump structures 302 and 303) may be substantially trapezoidal. It should be understood that when the term “substantially” is used to modify a degree or relationship, the covered range is not limited to that specific degree or relationship itself, but also includes its overall variation range. For example, a “substantial amount” may include a range of at least 95%. In the present disclosure, the expression “substantially trapezoidal,” as used to describe the bump structures, refers to a shape that, when viewed from the direction of the thickness side of the probe body (i.e., along the Y-axis direction), has an overall contour with one pair of approximately parallel sides and another pair of non-parallel sides, presenting a wider-narrower profile, even though the shape may not be geometrically perfect or ideally symmetrical. For instance, if the deviation of the slant angles of both sides from an ideal trapezoid is within ±10 degrees and such geometric deviation does not affect the bump structure's ability to perform its positioning, guiding, or alignment functions, the shape is still regarded as “substantially trapezoidal” within the meaning of the present invention.

FIG. 3B illustrates a partial structure of the vertical contact probe shown in FIG. 3A. More specifically, FIG. 3B illustrates a region of the probe body 116 corresponding to the positions of the bump structures 302 and 303 in FIG. 3A. The bump structures 302 and 303 respectively have contact surfaces 304 and 305. During testing, when the probe body 116 elastically deforms (i.e., buckles) under axial compression, the bump structures 302 and 303 can contact each other through their respective contact surfaces during deformation and generate a restricted relative sliding motion. In other words, the probe arms remain capable of sliding relative to each other while in contact. Through this sliding behavior, local stress concentration caused by direct contact can be dispersed, and part of the elastic strain energy can be absorbed. The term “restricted relative sliding” refers to a condition in which the two bump structures (such as 302 and 303) can move relative to each other along a specific direction after contact, but the sliding range is limited by the geometric configuration, material elasticity, or the design of external guiding components, thereby preventing excessive movement or loss of positioning functionality of the probe arms. The sliding range and direction can be adjusted by controlling the dimensions or tolerance of the bumps or by designing cooperating surfaces such as stop faces, limit slopes, or friction-control surfaces. Through this mechanism, the probe can release local energy when subjected to axial loading, thereby reducing the risk of arm damage while maintaining overall guiding capability and recoverability of the structure.

Moreover, the sliding motion helps reduce wear and deformation caused by contact between the probe arms and maintains a stable spatial relationship between the arms (e.g., the spacing between the two arms of the same probe), which contributes to impedance control for high-frequency signals such as differential signals. Compared with probes in the prior art that lack bump structures or have bump structures only on one side, maintaining the spatial relationship between probe arms also results in a smaller spacing between the probe bodies of adjacent probes within the same probe pair. In other words, during testing, as the internal spacing between arms of each probe decreases due to mutual approach, the extent of spacing expansion between adjacent probes is correspondingly reduced. Maintaining sufficiently close spacing between the probe bodies of adjacent probes in a probe pair further improves electrical performance in high-speed or high-frequency testing.

In some embodiments, each bump structure may have a width 306 (i.e., the height of the trapezoid) in the width direction, and each probe arm, at a portion corresponding to the bump structure (e.g., within the region illustrated in FIG. 2C), may have a width 307 in the width direction (i.e., along the X-axis direction in the figure). The width 306 of each bump structure may be not greater than the width 307 of the probe arm. In other words, the combined widths of each probe arm and its corresponding bump structure (e.g., width 308 shown in FIG. 3B) may be greater than one and not greater than two times the width of the same probe arm structure (e.g., width 307 shown in FIG. 3B). That is, the bump structure may have a maximum width equal to the width of the probe arm at the same position, thereby allowing proper abutment with the opposing bump structure. In some embodiments, the sum of the widths of each probe arm and its corresponding bump structure (e.g., width 308 shown in FIG. 3B) may be 1.05 to 1.6 times the width of the same bump structure (e.g., width 306 shown in FIG. 3B).

In some embodiments, the material of the bump structure may be identical to that of the probe body. In this case, the bump structure can be formed integrally during the same slitting process used to form the slit in the probe body. In other embodiments, the bump structure may be made of a material different from that of the probe body, and may include, but is not limited to, metallic alloys, engineering plastics, polymeric elastomers, or ceramic materials. In such cases, the bump structure may be attached to the probe body by, for example, welding, adhesive bonding, structural embedding, laser fusion, or micromechanical joining, thereby ensuring stability and functionality under loading conditions. The use of dissimilar materials facilitates optimization of sliding friction characteristics, stress distribution, wear resistance, or energy absorption capability, thereby further improving overall structural performance and lifespan.

FIG. 3C illustrates a partially enlarged view of the probe body of the vertical contact probe during a testing process according to one or more embodiments of the present invention. More specifically, FIG. 3C shows the buckling state of two probe arms within a vertical contact probe during testing, as well as the contact and relative sliding behavior between their bump structures. The region 310 shown in FIG. 3C depicts the two bump structures contacting each other through their respective contact surfaces and producing restricted relative sliding. The regions 309 and 311 respectively illustrate the areas above and below the bump structures. Although the contact between the two bump structures in region 310 effectively maintains the basic spacing between the probe arms, preventing the two arms from touching each other under most deformation conditions, it should be understood that under extreme bending or excessive compression, local contact between the arms in these regions may still occur.

In some embodiments, both ends of each probe in a probe pair may be offset from each other by a first distance along a direction parallel to the width side of the transverse cross-section of the probe body (e.g., along the X-axis direction shown in FIG. 3C) by the upper guide plate unit and the lower guide plate unit, as shown in FIG. 3C. In some embodiments, each probe may further be offset by a second distance, smaller than the first distance, along a direction parallel to the thickness side of the transverse cross-section of the probe body (e.g., along the Y-axis direction shown in FIG. 3C) by the upper guide plate unit and the lower guide plate unit.

FIG. 3D illustrates a further enlarged view of the bump structures shown in FIG. 3C. When the two bump structures contact each other and slide relative to each other, the amount of sliding can be represented by the spacing 314 between the respective centerlines 312 and 313 of the two bump structures.

In some embodiments, the length of each contact surface of the bump structures may be not smaller than the amount of relative sliding movement between the two bump structures. Taking FIG. 3B as an example, when the two bump structures are structurally identical, the length 315 of the contact surfaces of the two bump structures may be not smaller than the amount of relative sliding movement between the two bump structures, i.e., the spacing 314 described above. In some embodiments, the length of each contact surface of the bump structures may be not smaller than 10 micrometers.

The present invention provides bump structures capable of relative sliding with respect to each other, thereby enabling the probe to achieve controlled deflection and buffered contact during compression and buckling operations. Compared with conventional fixed-type bump designs, which merely provide restriction without sliding capability (i.e., bumps formed only on one of the probe arms), the relative sliding behavior of the bumps in the present invention facilitates the guidance and stabilization of a consistent deflection direction of the probe arms. Consequently, a multi-probe array can maintain orderly alignment and uniform spacing during compression, which is particularly critical for impedance matching and transmission stability of high-frequency signals. In addition, the relative sliding mechanism effectively disperses localized stress concentration generated by contact, reducing wear and the risk of permanent deformation of the probe arm structure, thereby improving the overall durability and reliability of the probe.

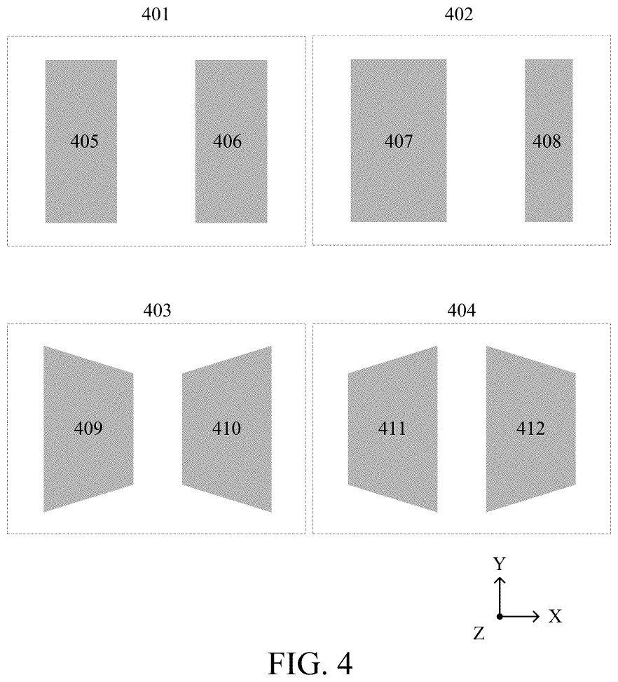

Referring to FIG. 4, various transverse cross-sections of probe bodies according to one or more embodiments of the present invention are illustrated. FIG. 4 shows cross-sections 401, 402, 403, and 404, which are taken from the probe body in different embodiments in a manner similar to that of FIG. 2B. The cross-section 401 includes two probe arms, namely probe arms 405 and 406. The cross-section 402 includes two probe arms, namely probe arms 407 and 408. The cross-section 403 includes two probe arms, namely probe arms 409 and 410. The cross-section 404 includes two probe arms, namely probe arms 411 and 412.

In some embodiments, the transverse cross-sections of the two probe arms may each be substantially rectangular, as shown in cross-sections 401 and 402. In other embodiments, the transverse cross-sections of the two probe arms may each be substantially trapezoidal, as shown in cross-sections 403 and 404.

The two-arm transverse cross-sections shown in FIG. 4 are obtained by cutting the probe arms on an X-Y plane perpendicular to the longitudinal development axis (Z-axis) at the same or different heights. As illustrated by the four cross-sections 401, 402, 403, and 404, the shapes of the probe arms in different embodiments may slightly vary along the same or different longitudinal positions and can generally be classified as “substantially rectangular” or “substantially trapezoidal.” The term “substantially trapezoidal” refers to a cross-sectional contour having one pair of approximately parallel sides and another pair of non-parallel sides, presenting an overall wider-narrower profile. For example, the cross-sections corresponding to 116c, 117c, 116d, and 117d shown in the figure are regarded as “substantially trapezoidal.” If the inclination deviation of the slanted sides from an ideal trapezoid is within ±10 degrees and such deviation does not affect the guiding, alignment, or contact functions, the shape is considered “substantially trapezoidal” within the meaning of the present invention.

The term “substantially rectangular” as used herein refers to a cross-sectional contour that may not be a geometrically perfect rectangle but has four approximately straight sides, with opposite sides being substantially parallel and corner angles being approximately right angles (e.g., 90±5 degrees). Minor edge rounding, chamfers, or manufacturing tolerances do not affect the rectangular functionality and guiding effect of the structure. For example, as shown by probe arms 405, 406, 407, and 408 in FIG. 4, the cross-sectional shapes of these probe arms exhibit stable guiding characteristics suitable for cooperation with guide plates or limiting structures to suppress rotation and lateral displacement.

The term “substantially trapezoidal” refers to a cross-sectional contour having one pair of approximately parallel sides and another pair of non-parallel sides, presenting an overall shape that is wider at one end and narrower at the other. For instance, probe arms 409, 410, 411, and 412 illustrated in the figure belong to this category. If the inclination deviation of the slanted sides from an ideal trapezoid does not exceed ±10 degrees and does not impair the guiding, alignment, or contact functions, the shape is regarded as “substantially trapezoidal” within the meaning of the present invention.

The term “guiding property” as used herein refers to the geometric design of a probe or probe arm that enables it to be guided and constrained to move in a specific direction during testing or assembly positioning, thereby preventing twisting, tilting, or lateral displacement and improving overall probe alignment accuracy and testing reliability.

In some embodiments, the two probe arms of a probe may have transverse cross-sectional contours of the same shape but different widths along the direction parallel to their width sides (i.e., the X-axis direction). In other words, the thickness or width of the probe arms may be asymmetrically configured. Such an asymmetric design can be adjusted according to actual stress distribution, guiding requirements, or spatial constraints to optimize structural strength, deformation behavior, or signal transmission stability.

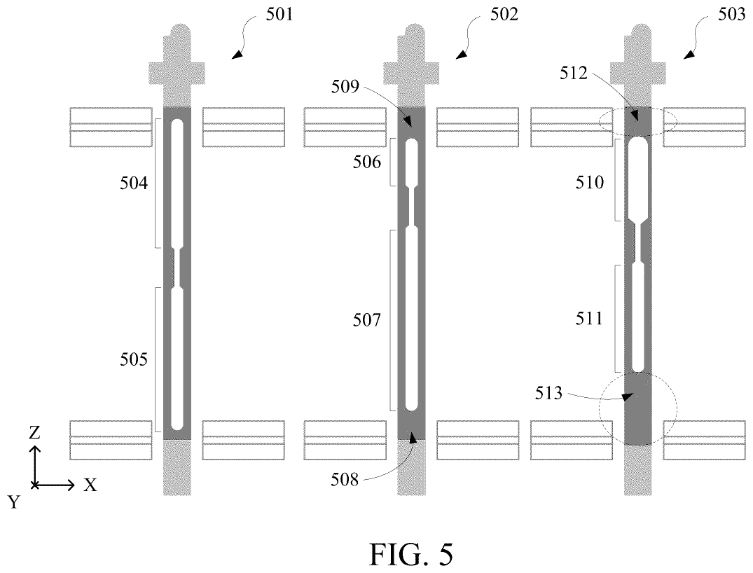

Referring to FIG. 5, various side-view structures of probes according to one or more embodiments of the present invention are illustrated. The contents shown in FIG. 5 can be divided into left, middle, and right sections. Each section illustrates, by way of one vertical contact probe (i.e., vertical contact probes 501, 502, and 503) together with schematic upper and lower guide plate units, the arrangement of the bump structures and the slit in the probe body according to one or more embodiments of the present invention. As previously described, in probes having a slit and bump structures in the probe body, the slit divides the probe body into multiple probe arms. For ease of explanation, FIG. 5 illustrates the case of one slit and two probe arms, with at least one upper key portion being disposed in a guide hole of the upper guide plate unit. The presence of the bump structures divides the probe arms and the slit into upper and lower regions. Depending on the relative positions of the bump structures, the lengths of the two regions may be identical or different.

In the embodiment corresponding to the vertical contact probe 501, the two bump structures divide the slit and the probe arms on both sides into two equal-length regions, i.e., regions 504 and 505. The bump structures are positioned at a height corresponding to the midpoint of the slit along the longitudinal development axis (Z-axis). In other words, the two bump structures are located at an intermediate position between the upper key portion and the lower key portion. This arrangement is advantageous for making the distribution of electrical resistance along the probe body more uniform when current flows through it.

In the embodiment corresponding to the vertical contact probe 502, the two bump structures divide the slit and the probe arms on both sides into two regions, i.e., regions 506 and 507, where the bump structures are positioned closer to the upper key portion 509 than to the lower key portion 508 along the longitudinal development axis (Z-axis). Therefore, the divided region 506 is relatively closer to the upper key portion 509 and farther from the lower key portion 508, while region 507 is relatively closer to the lower key portion 508 and farther from the upper key portion 509. In other words, the length of region 506 along the longitudinal development axis (Z-axis) is shorter than that of region 507.

In the embodiment corresponding to the vertical contact probe 503, the configuration of the two bump structures is similar to that of the probe 502, in which the slit and the probe arms on both sides are divided into an upper region 510 and a lower region 511, and the bump structures are positioned closer to the upper key portion 512 than to the lower key portion 513 along the longitudinal development axis (Z-axis). The difference between the vertical contact probe 503 and the probe 502 lies in that the probe arms in the upper and lower regions of probe 502 have the same width, whereas in probe 503, the probe arms in the upper and lower regions (i.e., region 510 and region 511) have different widths. More specifically, in the embodiment corresponding to the vertical contact probe 503, the probe arm in region 510 is narrower than that in region 511. In other words, the upper portion of the probe arm near the probe tail is thinner, and the lower portion near the probe tip is thicker. The variation in probe arm width (thickness) is related to the bending characteristics or mechanical response behavior of the probe during use.

It should be noted that although, in the figures of the present invention, the two probe arms divided by the slit are illustrated as having the same width, in some embodiments, the widths of the two probe arms divided by the slit may be different (i.e., the left and right probe arms shown in the figures may have unequal widths).

In addition to the difference in probe arm width (thickness) between the upper and lower regions, the slit position in the probe body (i.e., the positions of the upper and lower ends of the slit) and the lengths of the key portions may also influence the structural strength or elasticity of the probe during testing. More specifically, taking the vertical contact probe 503 as an example, the length of the lower key portion 513 may be greater than the length of the upper key portion 512. In other words, the distance between the lower end of the slit and the probe tip may be greater than the distance between the upper end of the slit and the probe tail.

In some embodiments, a method for testing an electronic device under test (DUT) may be further provided. The method may comprise a step of providing a probe system. The probe system may be the probe system 101 as described in the foregoing embodiments. The method may further comprise steps of positioning the probe head relative to the electronic DUT, and pressing the vertical contact probe into contact with the electronic DUT to measure at least one electronic characteristic of the electronic DUT. The electrical characteristic may refer to, for example, a current, voltage, resistance, capacitance, impedance, or signal integrity parameter of the electronic DUT. During testing, the probe tip of each vertical contact probe may contact a corresponding contact pad of the electronic DUT under an applied overdrive displacement, thereby establishing an electrical connection between the DUT and external test equipment. The obtained test data may be used to evaluate functional performance, continuity, or reliability of the electronic DUT. The above testing method may be implemented using the multilayer probe structure and sliding-guiding mechanism as described in the foregoing embodiments, thereby maintaining stable alignment and electrical consistency during high-frequency or high-speed testing.

It should be understood that although the drawings illustrate only one pair of bump structures disposed within a single slit, this is merely for the purpose of illustration and does not constitute an absolute limitation on the number of slits or bump structures. In some embodiments, multiple pairs of bump structures may be disposed within one slit. These bumps may be distributed along the longitudinal development axis (Z-axis) either at equal intervals or at unequal intervals on the two probe arms divided by the slit. Such a configuration can further enhance the guiding stability and structural support between the probe arms, while allowing the sliding characteristics and contact response to be adjusted according to actual requirements.

It should also be understood that although the drawings illustrate the probe having one slit and two probe arms, this is merely for ease of explanation and does not constitute an absolute limitation on the number of slits or probe arms. In some embodiments, multiple slits may be provided in the probe body. Since the probe arms are formed by being divided by the slits, the probe may thus have a structure with more than two probe arms through the use of multiple slits. The arrangement of bump structures between adjacent probe arms within the same slit can refer to the relevant descriptions disclosed herein with respect to the figures, and the design principles and functions described herein may likewise be applied to multi-slit and multi-arm structural configurations.

The term “direction of a specific side” (e.g., long side, wide side, or thick side), “direction of a specific dimension” (e.g., length, width, or thickness), or “direction of a specific axis” (e.g., X-axis, Y-axis, Z-axis, or longitudinal development axis) as used herein refers to a direction that is substantially parallel to the corresponding specific side or axis. In other words, unless otherwise expressly stated, any description referring to a direction “along a specific side” or “along a specific axis” shall be understood as referring to a direction substantially parallel to that side or axis.

In summary, the present invention provides a multilayer vertical contact probe suitable for functional testing of semiconductor wafers or packaged devices. The invention is characterized by the configuration of the key portions at the ends of the slit in relation to the guide holes or guide plates, combined with a sliding-guiding mechanism formed by bump structures between the probe arms. Through this dual design, the probe can effectively control the deflection and buckling of the probe arms caused by axial compression (overdrive) during testing, while maintaining excellent mechanical stability and electrical consistency in high-frequency or high-speed signal transmission.

In terms of the configuration of guide holes and guide plates, the present invention provides various positional arrangements, including: both upper and lower key portions being disposed within guide holes corresponding to inner layers (as shown in FIG. 2F) to provide the strongest reinforcement through deep-hole confinement, suitable for high-load or high-current testing; both upper and lower key portions being disposed within guide holes corresponding to outer layers (as shown in FIG. 2D) to provide early guiding and reduce initial deflection when the probe first enters the guide plate structure; the upper and lower key portions being respectively positioned at inner and outer layers (as shown in FIGS. 2C and 2G), thereby combining the advantages of deep reinforcement and early guiding; and one key portion being positioned within a guide hole while the other key portion is suspended between the guide plate units (as shown in FIGS. 2E and 2H) to provide constraint on one side and elastic buffering on the other. Through these diverse guide plate layer configurations, optimal design can be achieved according to different testing requirements, such as high-speed signal alignment or high-current stress distribution.

Regarding the bump structures, the present invention provides at least one pair of symmetrical bumps disposed on the opposing inner wall surfaces of the two adjacent probe arms within the slit of the probe body. During compression or buckling operation of the probe, the two bumps engage each other through contact surfaces and perform restricted relative sliding. This sliding mechanism achieves the following effects: dispersing localized contact stress and reducing the risk of fatigue fracture of the probe arms; suppressing direct friction and wear between the probe arms to extend probe lifespan; maintaining spatial structural relationships between the probe arms and between probe pairs to prevent impedance variation caused by arm convergence during high-frequency or high-speed testing; and further optimizing sliding friction characteristics, stress distribution, and energy absorption through the design of bump geometry (such as a substantially trapezoidal shape), dimensional ratios, and material selection.

By combining the two aforementioned features, the multilayer probe of the present invention can simultaneously ensure mechanical reliability and electrical stability under conditions of fine pitch and high-density layouts. Particularly in high-speed testing scenarios involving multiple differential signal probe pairs arranged in parallel, the design of the present invention can significantly reduce signal distortion caused by deflection and impedance instability, thereby enhancing overall testing accuracy and repeatability. As the number of differential signal pairs increases, the overall improvement effect becomes even more pronounced, making the invention particularly suitable for submicron-level wafer testing or high-frequency package testing environments.

The above embodiments are only examples for illustrating the present invention, and are not intended to limit the scope of the present invention. Any other embodiments produced by modifying, changing, adjusting, or integrating the above-mentioned embodiments shall be substantially covered in the scope claimed in the present invention as long as they are not difficult for a person having ordinary skill in the art to contemplate. The scope of the present invention shall be determined by the claims as listed.

1. A probe head for functionally testing an electronic device under test integrated in a semiconductor wafer, comprising:
a plurality of vertical contact probes, each vertical contact probe having a probe tip, a probe tail, and a probe body, wherein the probe tip is configured to contact a corresponding pad of the electronic device under test during testing, and the probe body extends along a longitudinal axis between the probe tail and the probe tip; and
an upper guide plate unit and a lower guide plate unit;
wherein, in each of the vertical contact probes:
the probe body has a width in a width direction and a thickness in a thickness direction, the width direction being substantially perpendicular to the thickness direction and also substantially perpendicular to the longitudinal axis; and
the probe body has a multilayer structure comprising a plurality of probe arms and at least one slit, the plurality of probe arms being arranged along the width direction and separated by the at least one slit, the at least one slit penetrating the probe body along the thickness direction, the plurality of probe arms converging at an upper key portion and a lower key portion, the upper key portion and the lower key portion respectively having corresponding guide holes in the upper guide plate unit and the lower guide plate unit for accommodating the vertical contact probe, and at least one of the upper key portion and the lower key portion being located within its corresponding guide hole.

2. The probe head of claim 1, wherein the lower guide plate unit and the upper guide plate unit each comprise a plurality of layers.

3. The probe head of claim 2, wherein thicknesses of the plurality of layers are not entirely identical.

4. The probe head of claim 2, wherein:
the plurality of layers respectively comprised in the lower guide plate unit and the upper guide plate unit comprise an inner guide plate and an outer guide plate, wherein the inner guide plate of the upper guide plate unit is closer to the lower guide plate unit than the outer guide plate of the upper guide plate unit, and the inner guide plate of the lower guide plate unit is closer to the upper guide plate unit than the outer guide plate of the lower guide plate unit; and
the upper key portion is located, within the corresponding guide hole of the upper guide plate unit, at a position corresponding to the outer guide plate.

5. The probe head of claim 2, wherein:
the plurality of layers respectively comprised in the lower guide plate unit and the upper guide plate unit comprise an inner guide plate and an outer guide plate, wherein the inner guide plate of the upper guide plate unit is closer to the lower guide plate unit than the outer guide plate of the upper guide plate unit, and the inner guide plate of the lower guide plate unit is closer to the upper guide plate unit than the outer guide plate of the lower guide plate unit; and
the lower key portion is located, within the corresponding guide hole of the lower guide plate unit, at a position corresponding to the inner guide plate.

6. The probe head of claim 1, wherein a diameter of each vertical contact probe gradually increases in a section extending from the probe tail to the upper key portion, and gradually increases in a section extending from the probe tip to the lower key portion.

7. The probe head of claim 1, wherein the multilayer structure of the probe body comprises two probe arms, the two probe arms respectively have a bump structure within a slit adjacent to the two probe arms, thereby forming two bump structures that face each other within the slit adjacent to the two probe arms, and the two bump structures are disposed, along a direction of the longitudinal axis, between the upper key portion and the lower key portion.

8. The probe head of claim 7, wherein the two bump structures each have a contact surface, and when the probe body undergoes buckling during testing, the two bump structures contact each other through the respective contact surfaces and restricted relative sliding occurs between the contact surfaces.

9. The probe head of claim 8, wherein a length of each contact surface is not less than 10 micrometers.

10. The probe head of claim 7, wherein when the probe body does not undergo buckling, the two bump structures are separated from each other in the width direction.

11. The probe head of claim 7, wherein the two bump structures are located at a middle position between the upper key portion and the lower key portion.

12. The probe head of claim 7, wherein when the two bump structures are viewed from the thickness direction, the two bump structures each present a substantially trapezoidal shape.

13. The probe head of claim 7, wherein a total width of each probe arm and its corresponding bump structure is 1.05 to 1.6 times a width of the same bump structure.

14. The probe head of claim 1, wherein the width direction is parallel to a bending direction of the plurality of probe arms when the vertical contact probe contacts the electronic device under test.

15. The probe head of claim 1, wherein a thickness of the probe body is greater than or equal to a width of the probe body.

16. The probe head of claim 1, wherein a cross-section of each of the plurality of probe arms is taken perpendicular to the longitudinal axis and is substantially rectangular or substantially trapezoidal.

17. The probe head of claim 1, wherein the multilayer structure of the probe body comprises two probe arms, and the two probe arms are, in a cross-section of the probe body, symmetrical about a slit adjacent to the two probe arms.

18. The probe head of claim 1, wherein shapes of cross-sections respectively formed by the plurality of probe arms are identical, but widths of the cross-sections in the width direction are different.

19. The probe head of claim 1, wherein two ends of each vertical contact probe are offset from each other in the thickness direction by a first distance between the upper guide plate unit and the lower guide plate unit.

20. The probe head of claim 19, wherein two ends of each vertical contact probe are further offset from each other in the width direction by a second distance between the upper guide plate unit and the lower guide plate unit, and the second distance is greater than the first distance.

21. The probe head of claim 1, wherein at least one of the upper key portion and the lower key portion abuts against a wall of the corresponding guide hole.

22. A probe card for functionally testing an electronic device under test integrated in a semiconductor wafer, comprising:
a circuit board;
a space transformer disposed on the circuit board; and
the probe head of claim 1, disposed on another side of the space transformer opposite to the circuit board, wherein a probe tail of each vertical contact probe of the probe head is configured to be electrically connected to the space transformer.

23. A probe system for functionally testing an electronic device under test integrated in a semiconductor wafer, comprising:
a wafer chuck configured to support the semiconductor wafer;
test equipment configured to be electrically connected to the electronic device under test to establish an electrical test procedure; and
the probe card of claim 22, disposed on the test equipment.

24. A method for testing an electronic device under test (DUT), comprising:
providing the probe system of claim 23;
positioning the probe head relative to the electronic DUT; and
pressing the vertical contact probe into contact with the electronic DUT to measure at least one electronic characteristic of the electronic DUT.

25. An electronic device under test tested by the method of claim 24.
